(19) United States
(12) Patent Application Publication
(10) Pub. No.: US 2025/0143088 A1
(43) Pub. Date: May 1, 2025

(54) DISPLAY PANEL AND DISPLAY DEVICE

(71) Applicants: Hefei Visionox Technology Co., Ltd., Hefei (CN); KunShan Go Visionox Opto Electronics Co., Ltd, Kunshan (CN)

(72) Inventors: Wenyu ZENG, Hefei (CN); Ying SHEN, Hefei (CN); Pengle DANG, Hefei (CN); Lixiong XU, Hefei (CN); Jingui LIU, Hefei (CN); Shundong BAO, Hefei (CN)

(73) Assignees: Hefei Visionox Technology Co., Ltd., Hefei (CN); KunShan Go Visionox Opto Electronics Co., Ltd, Kunshan (CN)

(21) Appl. No.: 18/678,407

(22) Filed: May 30, 2024

(30) Foreign Application Priority Data
Oct. 31, 2023 (CN) 202311451935.7

(51) Int. Cl. H10K 59/122; H10K 59/35

(52) U.S. Cl. CPC H10K 59/122; H10K 59/353

(57) ABSTRACT

A display panel and a display device. A display panel includes: a base plate, an isolation structure with isolation openings and first openings, first light-emitting units and second light-emitting units, first electrodes including first sub-electrodes and second sub-electrodes, and second electrodes. An orthographic projection of the second electrode on the base plate is offset from an orthographic projection of the first opening on the base plate. The first light-emitting units and the second light-emitting units are disposed in the isolation openings and in the first openings, respectively. The first sub-electrodes are disposed at a side of the first light-emitting units away from the base plate and the second sub-electrodes are disposed in the first openings and located at a side of the second light-emitting units away from the base plate.

### CROSS REFERENCE TO RELATED APPLICATIONS

The present application claims priority to Chinese patent application No. 202311451935.7, filed on Oct. 31, 2023 and entitled with “DISPLAY PANEL AND DISPLAY DEVICE”, which is incorporated herein by reference in its entirety.

### TECHNICAL FIELD

The present application relates to the field of display device technology, and in particular, to a display panel and a display device.

### BACKGROUND

A flat display device based on an Organic Light Emitting Diode (OLED), a Light Emitting Diode (LED) or the like has been widely used in various consumer electronic products such as a mobile phone, a TV, a notebook computer, a desktop computer due to advantages of its higher image quality, power saving, thinner body and wider range of applications, and becomes the mainstream of display devices.

### SUMMARY

Embodiments of a first aspect of the present application provide a display panel, including: a base plate; a plurality of second electrodes disposed on the base plate and spaced apart from each other; an isolation structure, the isolation structure and the second electrodes are disposed at a same side of the base plate; a plurality of isolation openings and first openings surrounded by the isolation structure, the second electrode being exposed from the isolation opening, and an orthographic projection of the second electrode on the base plate is offset from an orthographic projection of the first opening on the base plate; a plurality of light-emitting units comprising a plurality of first light-emitting units and a plurality of second light-emitting units, the first light-emitting units are disposed in the isolation openings and located at a side of the second electrodes away from the base plate, and the second light-emitting units are disposed in the first openings; a plurality of first electrodes comprising a plurality of first sub-electrodes and a plurality of second sub-electrodes, the first sub-electrodes being disposed in the isolation openings, and located at a side of the first light-emitting units away from the base plate, at least a part of the first sub-electrode contacting with an inner wall of the isolation structure facing to the isolation opening, the second sub-electrodes being disposed in the first openings and located at a side of the second light-emitting units away from the base plate, and at least a part of the second sub-electrode contacting with an inner wall of the isolation structure facing to the first opening.

Embodiment of a second aspect of the present application provides a display panel, including: a base plate; an isolation structure disposed at a side of the base plate; a plurality of isolation openings and first openings surrounded by the isolation structure; and a plurality of sub-pixels comprising a plurality of light-emitting sub-pixels and a plurality of dummy sub-pixels, at least a part of the light-emitting sub-pixels are disposed in the isolation openings, and at least a part of the dummy sub-pixels are disposed in the first openings.

Embodiments of a third aspect of the present application further provide a display device, including the display panel according to any of the embodiments of the first aspect.

### BRIEF DESCRIPTION OF THE DRAWINGS

Other features, objects and advantages of the present application will become more apparent from reading the following detailed description of the non-limiting embodiments with reference to the accompanying drawings, in which the same or similar reference numerals represent the same or similar features.

FIG. 1 shows a schematic structural top view of a display panel according to an embodiment of the present application;

FIG. 2 shows an enlarged schematic structural diagram of a position B in FIG. 1 in an example;

FIG. 3 shows a cross-sectional view of FIG. 2 at a line A-A in an example;

FIG. 4 shows a cross-sectional view of FIG. 2 at the line A-A in another example;

FIG. 5 shows a cross-sectional view of FIG. 2 at the line A-A in yet another example;

FIG. 6 shows a cross-sectional view of FIG. 2 at the line A-A in yet another example;

FIG. 7 shows a cross-sectional view of FIG. 2 at the line A-A in yet another example;

FIG. 8 shows a cross-sectional view of FIG. 2 at the line A-A in yet another example;

FIG. 9 shows a cross-sectional view of FIG. 2 at the line A-A in yet another example;

FIG. 10 shows an enlarged schematic structural diagram of the position B in FIG. 1 in another example;

FIG. 11 shows an enlarged schematic structural diagram of the position B in FIG. 1 in yet another example;

FIG. 12 shows an enlarged schematic structural diagram of the position B in FIG. 1 in yet another example;

FIG. 13 shows an enlarged schematic structural diagram of the position B in FIG. 1 in yet another example;

FIG. 14 shows an enlarged schematic structural diagram of the position B in FIG. 1 in yet another example;

FIG. 15 shows an enlarged schematic structural diagram of the position B in FIG. 1 in yet another example.

### ILLUSTRATION OF REFERENCE NUMERALS

10: Display panel; 11: Sub-pixel; 111: Light-emitting sub-pixel; 112: Dummy sub-pixel;
100: Base plate;
200: Isolation structure; 210: Isolation opening; 220: First opening; 230: Isolation wall; 240: Barrier portion;
300: Light-emitting unit; 310: First light-emitting unit; 311: First sub-light emitting unit; 312: Second sub-light emitting unit; 320: Second light-emitting unit; 330: Third light-emitting unit;
400: First electrode; 410: First sub-electrode; 420: Second sub-electrode; 430: Third sub-electrode;
500: Conductive layer; 510: First sub-conductive layer; 511: First signal line; 520: Second sub-conductive layer; 521: Second signal line; 522: Second opening;
600: Second electrode;
700: Insulating layer; 710: Pixel opening; 720: Abdicating opening;
800: Encapsulation layer; 810: First encapsulation layer; 811: First encapsulation unit;
812: Second encapsulation unit; 820: Second encapsulation layer; 830: Third encapsulation layer;
x: First direction; y: Second direction; z: Thickness direction of the display panel; AA: Display area.

### DETAILED DESCRIPTION

Features and exemplary embodiments of various aspects of the present application will be described in detail below. Numerous specific details are set forth in the following detailed description to provide a thorough understanding of the present application. However, it will be apparent to a person skilled in the art that the present application may be practiced without some of these specific details. The following description of the embodiments is merely intended to provide a better understanding of the present application by illustrating examples of the present application. In the accompanying drawings and the following description, at least some of well-known structures and techniques are not shown so as to avoid unnecessary obscurity of the present application. In addition, size of some structures may be exaggerated for clarity. Furthermore, the features, structures, or characteristics described below may be combined in one or more embodiments by any suitable manner.

In the description of the present application, it should be noted that, unless otherwise specified, the term “a plurality of” indicates two or more; the terms “upper”, “lower”, “left”, “right”, “inner”, “outer”, and the like indicate orientations or positional relationships for facilitating and simplifying description of the present application, and do not indicate or imply that the involved devices or elements must have such a particular orientation, or must be constructed and operated in such a particular orientation, and thus should not be construed to limit the present application. In addition, the terms “first”, “second”, and the like are merely used for the purpose of description and should not be interpreted to indicate or imply relative importance.

The directional words appearing in the following description indicate directions shown in the drawings and do not limit the specific structure in the embodiments of the present application. In the description of the present application, it should be further noted that, unless otherwise clearly specified and limited, the terms “installation” and “connection” should be understood in a broad sense, for example, the “connection” may refer to a fixed, a detachable or an integrated connection; and it may refer to a director an indirect connection. For a person skilled in the art, the specific meaning of the terms mentioned above in the present application may be understood in accordance with specific situations.

The embodiments of the present application provide a display panel, including: a base plate; a plurality of second electrodes disposed on the base plate and spaced apart from each other; an isolation structure, the isolation structure and the second electrodes are disposed at a same side of the base plate; a plurality of isolation openings and first openings surrounded by the isolation structure, the second electrode being exposed from the isolation opening, and an orthographic projection of the second electrode on the base plate is offset from an orthographic projection of the first opening on the base plate; a plurality of light-emitting units comprising a plurality of first light-emitting units and a plurality of second light-emitting units, the first light-emitting units are disposed in the isolation openings and located at a side of the second electrodes away from the base plate, and the second light-emitting units are disposed in the first openings; a plurality of first electrodes comprising a plurality of first sub-electrodes and a plurality of second sub-electrodes, the first sub-electrodes being disposed in the isolation openings, and located at a side of the first light-emitting units away from the base plate, at least a part of the first sub-electrode contacting with an inner wall of the isolation structure facing to the isolation opening, the second sub-electrodes being disposed in the first openings and located at a side of the second light-emitting units away from the base plate, and at least a part of the second sub-electrode contacting with an inner wall of the isolation structure facing to the first opening.

With the present application in which the second sub-electrode is disposed in the first opening, the second sub-electrode functions as a shielding layer, which reduces parasitic capacitances generated within the display panel and improve operational performance of the display panel.

For a better understanding of the present application, a display panel and a display device according to the embodiments of the present application will be described in detail below with reference to the accompanying drawings. Here, the direction z in the accompanying drawings is a thickness direction of the display panel, the direction x in the accompanying drawings is a first direction, and the direction y in the accompanying drawings is a second direction. In the accompanying drawings, dimensions in the drawings are not necessarily to scale with actual dimensions for ease of illustration, and a portion of hierarchical structures in the display panel is not shown.

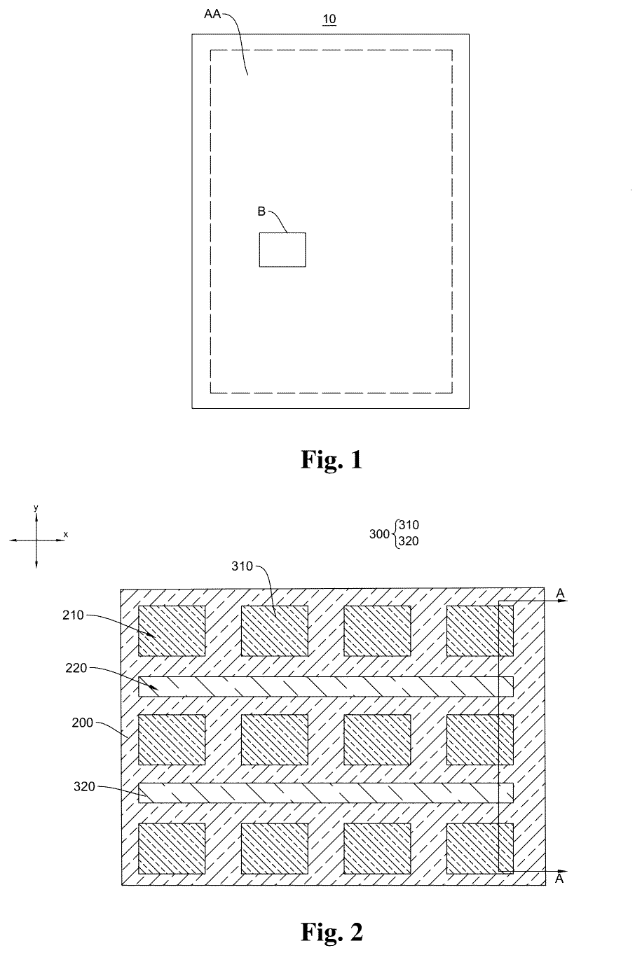

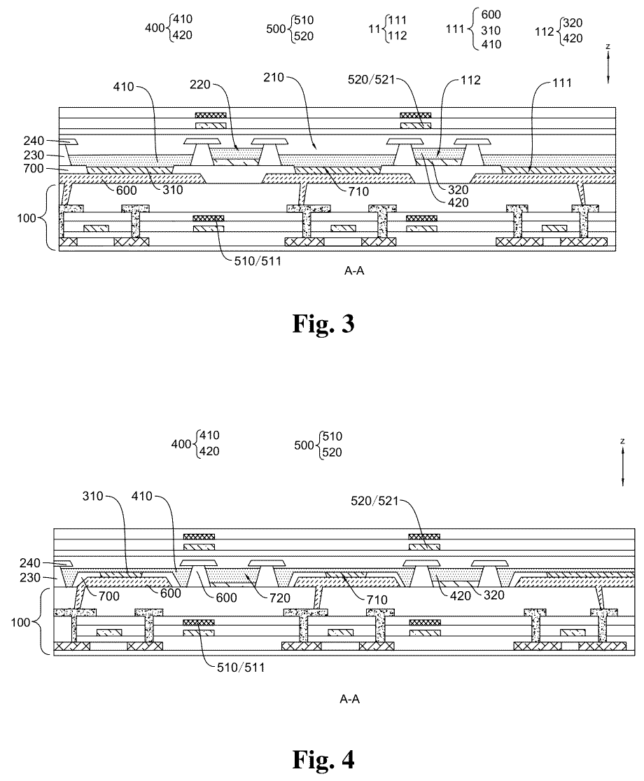

Referring to FIGS. 1 to 3, FIG. 1 shows a schematic structural top view of a display panel according to an embodiment of the present application, FIG. 2 shows an enlarged schematic structural diagram of a position B in FIG. 1 in an example, and FIG. 3 shows a cross-sectional view of FIG. 2 at a line A-A in an example. The position B is within a display area AA of the display panel 10. FIG. 2 is an enlarged schematic structural diagram after hiding of a conductive layer.

As shown in FIGS. 1 to 3, embodiments of a first aspect of the present application provide a display panel 10, including a base plate 100, an isolation structure 200, a plurality of light-emitting units 300, a plurality of first electrodes 400 and a plurality of second electrodes 600. The second electrodes 600 are disposed on the base plate 100 and spaced apart from each other. The isolation structure 200 and the second electrodes 600 are disposed at a same side of the base plate 100, a plurality of isolation openings 210 and first openings 220 are surrounded by the isolation structure 200, the second electrode 600 being exposed from the isolation opening 210, and an orthographic projection of the second electrode 600 on the base plate 100 is offset from an orthographic projection of the first opening 220 on the base plate 100. The light-emitting units 300 include a plurality of first light-emitting units 310 and a plurality of second light-emitting units 320, the first light-emitting units 310 are disposed within the isolation openings 210 and located at a side of the second electrodes 600 away from the base plate 100, and the second light-emitting units 320 are disposed in the first openings 220. The first electrodes 400 include first sub-electrodes 410 and second sub-electrodes 420, the first sub-electrodes 410 are disposed within the isolation openings 210 and located at a side of the first light-emitting units 310 away from the base plate 100, and at least a part of the first sub-electrode 410 contacts with an inner wall of the isolation structure 200 facing to the isolation opening 210; and the second sub-electrodes 420 are disposed within the first openings 220 and located at a side of the second light-emitting units 320 away from the base plate 100, and at least a part of the second sub-electrode 420 contacts with an inner wall of the isolation structure 200 facing to the first opening 220.

In some embodiments, when the display panel 10 is in use, the first light-emitting units 310 are powered to emit light, while the second light-emitting units 320 do not emit light, that is, the first openings 220 may function as light-transmitting openings. By making the first openings 220 as light-transmitting openings, a light transmittance of the display panel 10 can be improved, which in turn facilitates implementation of an under-screen camera and improvement of imaging effects of the under-screen camera. In addition, the first openings 220 may also be used for accommodating fingerprint wirings, so as to reduce an overall thickness of the display panel 10.

In some embodiments, the isolation structure 200 is used for partitioning the light-emitting units 300 and the first electrodes 400. The second light-emitting units 320 and the first light-emitting units 310 may be evaporated synchronously, and the second sub-electrodes 420 and the first sub-electrodes 410 may be evaporated synchronously. During evaporation, evaporation materials may fall into different openings, to form the separated light-emitting units 300 or the separated first electrodes 400 due to partition of the isolation structure 200. The first sub-electrode 410 includes a same material as the second sub-electrode 420. In some embodiments, the second electrode 600 and the first sub-electrode 410 are electrically connected with the first light-emitting unit 310 for supplying power to the first light-emitting unit 310. Specifically, one of the second electrode 600 and the first sub-electrode 410 may be an anode and the other one may be a cathode, and an example where the second electrode 600 is the anode and the first sub-electrode 410 is the cathode is taken in the embodiments of the present application for illustration. In the present application, no second electrode 600 is provided at a side of the second light-emitting unit 320 facing to the base plate 100, so only the first light-emitting unit 310 can be powered to emit light, while the second light-emitting unit 320 within the first opening 220 does not emit light due to lacking power from an anode but functions as a shielding layer.

In the display panel 10 according to the embodiments of the present application, the light-emitting units 300 and the first electrodes 400 are partitioned by the isolation structure 200, so a mask plate is not required when the light-emitting units 300 and the first electrodes 400 are evaporated, which saves costs of providing the mask plate and thus save manufacturing costs. By providing the second sub-electrode 420 in the first opening 220, the second sub-electrode 420 can function as a shielding layer, which reduces parasitic capacitance generated in the display panel 10 and improves operational performance of the display panel 10. By enabling synchronous evaporation of the second light-emitting units 320 and the first light-emitting units 310 and of the second sub-electrodes 420 and the first sub-electrodes 410, the second light-emitting units 320 and the second sub-electrodes 420 are manufactured without requiring additional steps, which simplifies flow and reduce costs of manufacturing the display panel 10.

In some optional embodiments, the display panel may further includes a conductive layer 500. The conductive layer 500 includes a first sub-conductive layer 510 disposed in the base plate 100 and a second sub-conductive layer 520 disposed at a side of the isolation structure 200 away from the base plate 100, the first sub-conductive layer 510 includes a first signal line 511, the second sub-conductive layer 520 includes a second signal line 521, and the first signal line 511 and the second signal line 521 are located at different sides of the first sub-electrode 410.

In some embodiments, the orthographic projection of the first opening 220 on the base plate 100 is at least partially located outside of an orthographic projection of the first signal line 511 on the base plate 100, and the orthographic projection of the first opening 220 on the base plate 100 is at least partially located outside of an orthographic projection of the second signal line 521 on the base plate 100.

Even if the first signal line 511 and the second signal line 521 are not necessarily facing to the first opening 220 directly, a parasitic capacitance will be generated between the first signal line 511 and the second signal line 521 via the first opening 220 under a condition that no shielding layer is provided within the first opening 220. When the first signal line 511 overlaps completely with the second signal line 521, the parasitic capacitance between the first signal line 511 and the second signal line 521 is maximum. Thus, even if the first signal line 511 is staggered from the second signal line 521, a parasitic capacitance will be generated between the first signal line 511 and the second signal line 521 via the first opening 220 under a condition that the shielding layer is provided within the first opening 220. By providing the second sub-electrode 420 within the first opening 220 in the present application, which includes a metal material and thus can function as a shielding layer, the parasitic capacitance generated in the display panel 10 can be reduced and the operational performance of the display panel 10 can be improved.

In some embodiments, an orthographic projection of the isolation opening 210 on the base plate 100 is at least partially located outside of the orthographic projection of the second signal line 521 on the base plate 100.

In some embodiments, the first signal line 511 may include at least one of a data line, a scanning line, a power supply signal line, or a voltage reference line. The base plate 100 may be arranged in various ways. The base plate 100 may include a substrate and a first conductive layer, a second conductive layer, a third conductive layer which are arranged at a side of the substrate and stacked, with an insulating layer disposed between adjacent conductive layers. One of the first conductive layer, the second conductive layer, and the third conductive layer may be disposed in a same layer as the first sub-conductive layer 510. Exemplarily, a pixel driving circuit in the base plate 100 may include a transistor and a storage capacitor, the transistor includes a bulk semiconductor with a gate, a source, and a drain and the storage capacitor includes a first electrode plate and a second electrode plate. In this case, exemplarily, the gate and the first electrode plate may be located in the first conductive layer, the second electrode plate may be located in the second conductive layer, and the source and the drain may be located in the third conductive layer.

In some embodiments, the second signal line 521 includes a touch wiring.

In the display panel 10 according to the embodiments of the present application, by making the orthographic projection of the first opening 220 on the base plate 100 be at least partially outside of the orthographic projection of the first signal line 511 on the base plate 100 and at least partially outside of the orthographic projection of the second signal line 521 on the base plate 100, a transmittance of the first opening 220 is increased. By disposing the second sub-electrode 420 within the first opening 220, the second sub-electrode 420 may function as a shielding layer, to reduce the parasitic capacitance generated between the first signal line 511 and the second signal line 521 and thus the operational performance of the display panel 10 can be improved. Referring to FIG. 6, it shows a cross-sectional view of FIG. 2 at the line A-A in yet another example.

As shown in FIG. 6, in some optional embodiments, the orthographic projection of the first opening 220 on the base plate 100 is located outside of the orthographic projection of the first signal line 511 on the base plate 100, and the orthographic projection of the first opening 220 on the base plate 100 is located outside of the orthographic projection of the second signal line 521 on the base plate 100.

In some embodiments, the orthographic projection of the second signal line 521 on the base plate 100 may overlap with or be located within an orthographic projection of the isolation structure 200 on the base plate 100. That is, the second signal line 521 is within a distribution range of the isolation structure 200. The orthographic projection of the first signal line 511 on the base plate 100 may overlap with or be located within the orthographic projection of the isolation structure 200 on the base plate 100. That is, the first signal line 511 is within a distribution range of the isolation structure 200.

In some embodiments, a width of the orthographic projection of the second signal line 521 on the base plate 100 is less than a distance between the isolation opening 210 and the first opening 220 adjacent to just the isolation opening on the isolation structure 200. In some embodiments, the width of the orthographic projection of the second signal lines 521 on the base plate 100 is less than a distance between the adjacent isolation openings 210 on the isolation structure 200. That is, a width of the second signal line 521 is less than a width of the isolation structure 200, so that influence of the second signal line 521 on light emission of the first light-emitting unit 310 can be reduced, and influence on light transmittance performance of the first opening 220 can also be reduced.

In some embodiments, the orthographic projection of the second signal line 521 on the base plate 100 may be located outside of an orthographic projection of the first light-emitting unit 310 on the base plate 100, and the orthographic projection of the second signal line 521 on the base plate 100 may be located outside of an orthographic projection of the second light-emitting unit 320 on the base plate 100.

In the display panel 10 according to the embodiments of the present application, by offsetting the first signal line 511 and the second signal line 521 from the first opening 220, the transmittance of the first opening 220 is further increased. By overlapping the orthographic projection of the second signal line 521 on the base plate 100 the orthographic projection of the isolation structure 200 on the base plate 100 or locating the orthographic projection of the second signal line 521 on the base plate 100 within the orthographic projection of the isolation structure 200 on the base plate 100, the second signal line 521 neither blocks light emission of the light emitting unit 300 nor reduces the transmittance of the first opening 220.

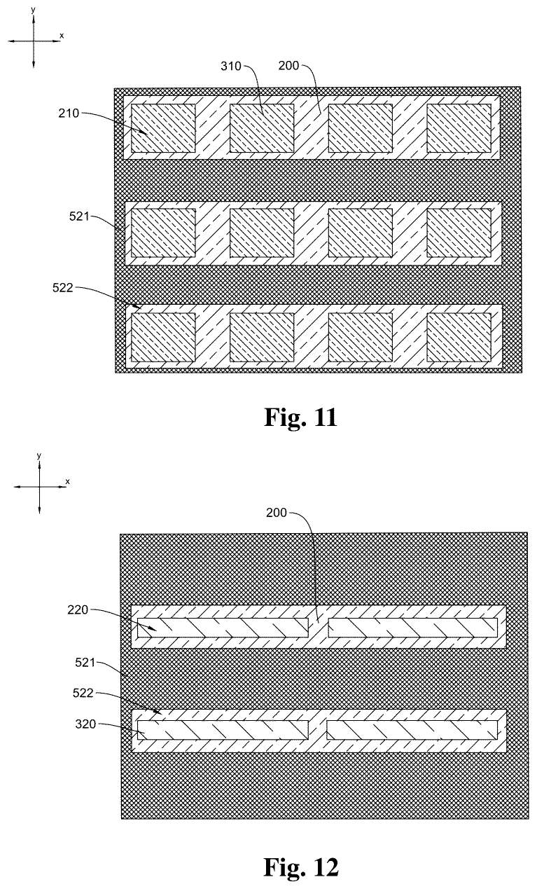

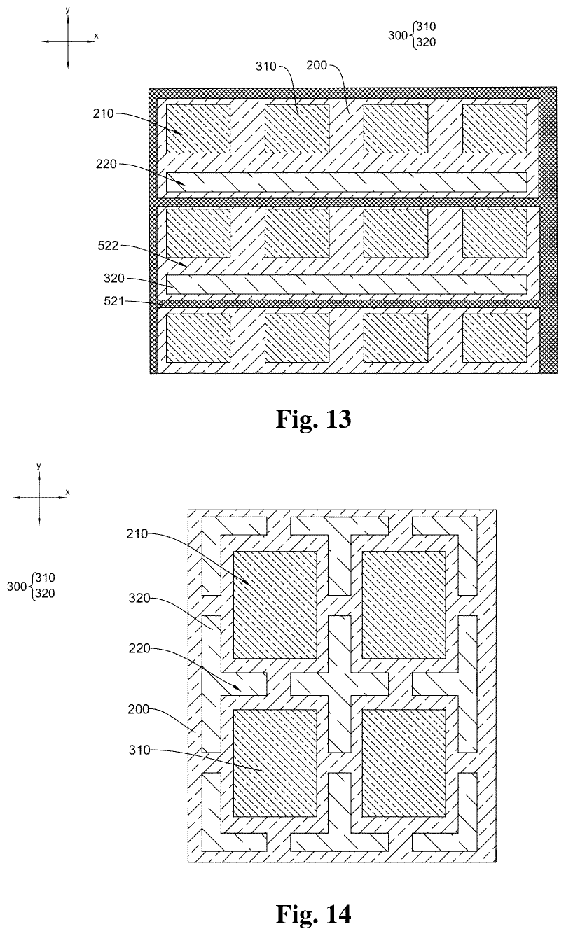

Referring to FIGS. 10 to 13, FIG. 10 shows an enlarged schematic structural diagram of the position B in FIG. 1 in another example, FIG. 11 shows an enlarged schematic structural diagram of the position B in FIG. 1 in yet another example, FIG. 12 shows an enlarged schematic structural diagram of the position B in FIG. 1 in yet another example, and FIG. 13 shows an enlarged schematic structural diagram of the position B in FIG. 1 in yet another example.

In some optional embodiments, the orthographic projection of the second signal line 521 on the base plate 100 is a grid mesh with second openings 522 surrounded by the second signal lines 521. An orthographic projection of at least one of the openings surrounded by the isolation structure 200 on the base plate 100 completely overlaps with or is located within an orthographic projection of the second opening 522 on the base plate.

In some embodiments, the orthographic projection of the isolation structure 200 on the base plate 100 is also in a grid mesh.

In some embodiments, the openings surrounded by the isolation structure 200 includes the isolation openings 210 and the first openings 220.

In some embodiments, the openings surrounded by the isolation structure 200 correspond to the second openings 522 in a one-to-one correspondence as shown in FIG. 10.

In some embodiments, orthographic projections of at least two of the openings surrounded by the isolation structure 200 on the base plate 100 is located within an orthographic projection of a same one of the openings surrounded by the second signal line 521 on the base plate 100. That is, the opening surrounded by the second signal line 521 is greater than the opening surrounded by the isolation structure 200. In some embodiments, a plurality of openings surrounded by isolation structure 200 and located in a same one of the second openings 522 are the isolation openings 210 (as shown in FIG. 11), or are the first openings 220 (as shown in FIG. 12), or include both the isolation openings 210 and the first openings 220 (as shown in FIG. 13).

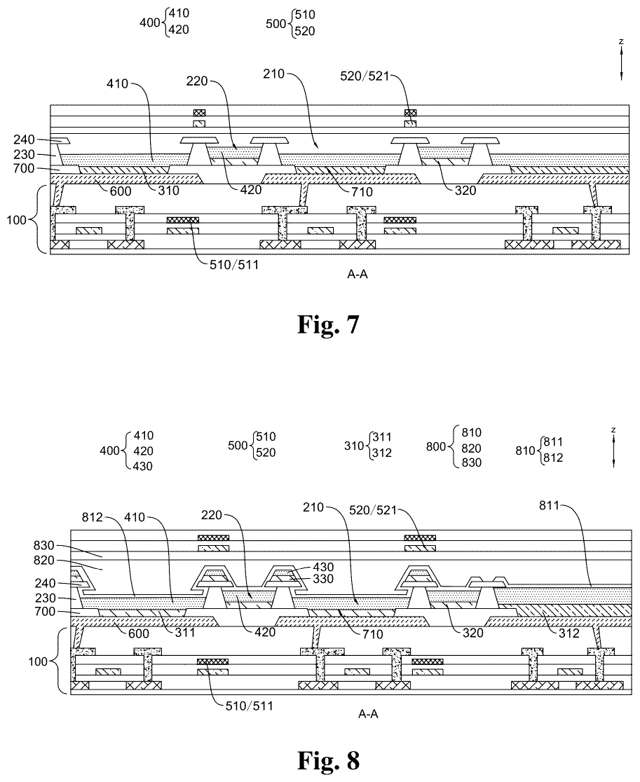

Referring to FIGS. 6 and 7, FIG. 7 shows a cross-sectional view of FIG. 2 at the line A-A in yet another example.

In some optional embodiments, the isolation structure 200 includes an isolation wall 230 and a barrier portion 240, the barrier portion 240 is disposed at a side of the isolation wall 230 away from the base plate 100, an orthographic projection of the isolation wall 230 on the base plate 100 is located within an orthographic projection of the barrier portion 240 on the base plate, and at least a part of the second sub-electrode 420 covers a side wall of the isolation wall 230 facing to the first opening 220.

In some embodiments, the orthographic projection of the second signal line 521 on the base plate 100 overlaps with an orthographic projection of the barrier portion 240 on the base plate 100 or is located within the orthographic projection of the isolation structure 200 on the base plate 100, as shown in FIG. 6.

In some embodiments, the orthographic projection of the second signal line 521 on the base plate 100 overlaps with or is located within an orthographic projection of the isolation wall 230 on the base plate 100, as shown in FIG. 7.

In the display panel 10 according to the embodiments of the present application, by locating the orthographic projection of the isolation wall 230 on the base plate 100 within the orthographic projection of the barrier portion 240 on the base plate 100, the isolation structure 200 can partition the light-emitting units 300 and the first electrodes, which results in that costs of providing a mask plate can be saved and thus manufacturing costs can be reduced.

In some optional embodiments, the isolation wall 230 may include an electrically conductive material, and first sub-electrodes 410 within at least two adjacent isolation openings 210 are electrically connected with the second sub-electrode 420 within the first opening 220 through the isolation wall 230.

In some embodiments, the first openings 220 are surrounded by the isolation wall 230, and an orthographic projection of the second sub-electrode 420 on the base plate 100 overlaps with the orthographic projection of the first opening 220 on the base plate 100. The first opening 220 may be a light-transmitting opening.

In the display panel 10 according to the embodiments of the present application, by using an electrically conductive material as the material of the isolation wall 230, the first sub-electrodes 410 and the second sub-electrode 420 are connected as an entire electrode, which facilitate an entire control of the display panel 10, and further reduces the parasitic capacitance generated between the first signal line 511 and the second signal line 521, and thus the operational performance of the display panel 10 can be further improved.

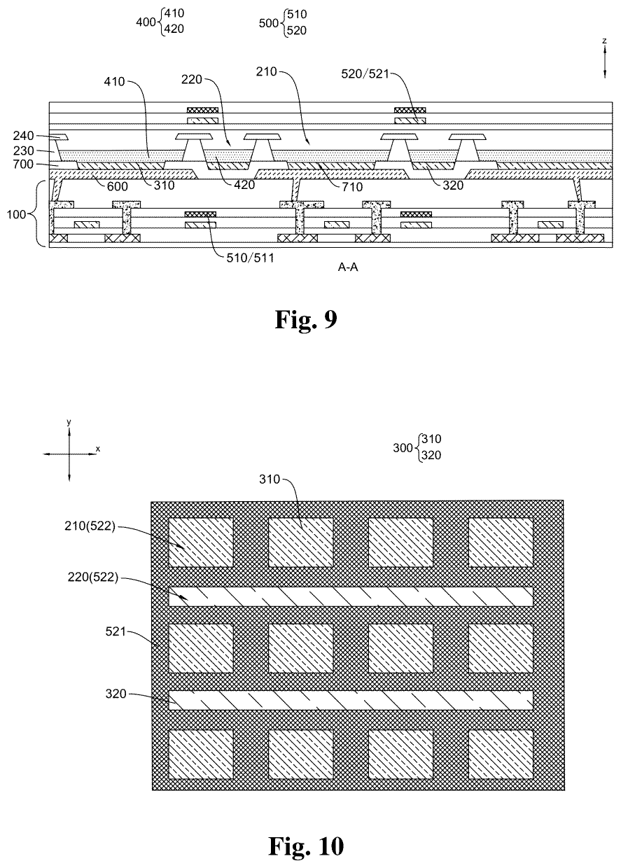

Referring to FIGS. 3, 4 and 9, FIG. 4 shows a cross-sectional view of FIG. 2 at the line A-A in another example, and FIG. 9 shows a cross-sectional view of FIG. 2 at the line A-A in yet another example.

In some optional embodiments, the display panel 10 may further include an insulating layer 700 disposed on the base plate, the insulating layer 700 includes a plurality of pixel openings 710, an orthographic projection of the pixel opening 710 on the base plate 100 is located within the orthographic projection of the isolation opening 210 on the base plate 100, and the pixel opening 710 is configured to accommodate the first light-emitting unit 310.

In some embodiments, the insulating layer 700 may be a pixel definition layer, and the isolation structure 200 is disposed at a side of the pixel definition layer away from the base plate 100 (as shown in FIG. 3), or the insulating layer 700 may include a plurality of abdicating openings 720, at least a part of the base plate 100 is exposed from the abdicating openings 720, and the isolation structure 200 is disposed on the part of the base plate 100 exposed from the abdicating openings 720 (as shown in FIG. 4).

In some embodiments, as shown in FIG. 9, the insulating layer 700 may be a pixel definition layer, and at least a part of the second light-emitting units is disposed at a side of the pixel definition layer away from the base plate 100.

In some embodiments, as shown in FIG. 9, the insulating layer 700 may be a pixel definition layer, and at least a part of the second light-emitting units 320 is located in the pixel definition layer. That is, the pixel definition layer may be provided with recesses or openings for accommodating the second light-emitting units 320, such that the second light-emitting units 320 can be disposed in a same layer as the pixel definition layer.

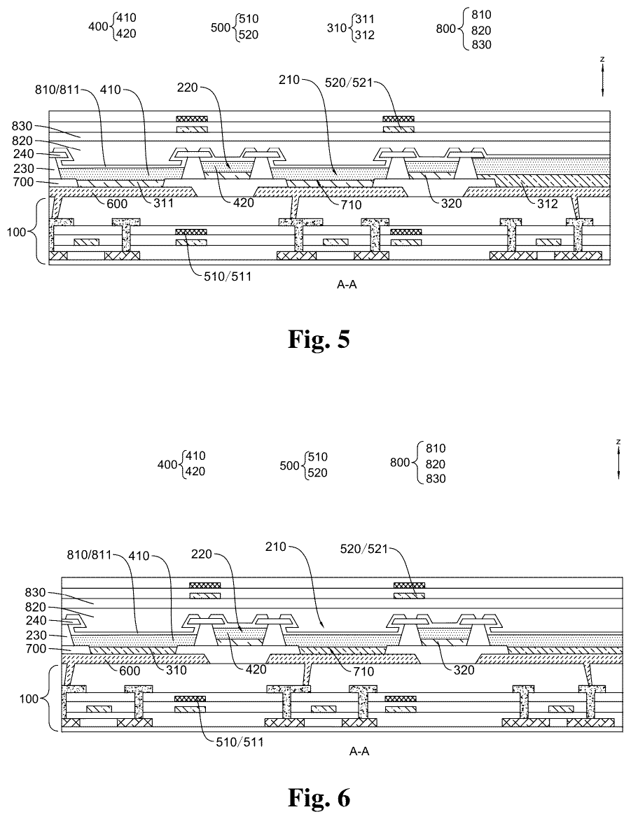

Referring to FIG. 5, FIG. 5 shows a cross-sectional view of FIG. 2 at the line A-A in in yet another example.

As shown in FIG. 5, in some optional embodiments, the first light-emitting units 310 may include a first light-emitting subunit 311 and a second light-emitting subunit 312 which are configured to emit light of different colors, a distance between a surface of the first light-emitting subunit 311 facing to the base plate 100 and a surface of the first light-emitting subunit 311 away from the base plate 100 is less than a distance between a surface of the second light-emitting subunit 312 facing to the base plate 100 and a surface of the second light-emitting subunit 312 away from the base plate 100, and a thickness of the first light-emitting subunit 311 is less than a thickness of the second light-emitting subunit 312.

In some embodiments, the first light-emitting subunit 311 may include a same material as the second light-emitting unit 320, such that the first light-emitting subunit 311 and the second light-emitting unit 320 may be manufactured in a same process. Since the second light-emitting unit 320 and the first light-emitting subunit 311 with a relatively thinner thickness can be manufactured in a same process, not only additional steps are not required for manufacturing, but also influences on the light transmittance performance of the first opening 220 can be further reduced as much as possible to increase the transmittance of the first opening 220.

In some embodiments, the distance between the surface of the first light-emitting subunit 311 facing to the base plate 100 and the surface of the first light emitting subunit 311 away from the base plate 100 is equal to a distance between a surface of the second light-emitting unit 320 facing to the base plate 100 and a surface of the second light-emitting unit 320 away from the base plate 100.

In some embodiments, the first light-emitting subunit 311 and the second light-emitting subunit 312 are configured to emit at least one of red light, green light or blue light.

In some embodiments, the first light-emitting units 310 may further include a third light-emitting subunit (not shown), the first light-emitting subunit 311, the second light-emitting subunit 312 and the third light-emitting subunit are configured to emit one of red light, green light, or blue light, respectively. The distance between the surface of the first light-emitting subunit 311 facing to the base plate 100 and the surface of the first light-emitting subunit 311 away from the base plate 100 is less than a distance between a surface of the third light-emitting subunit facing to the base plate 100 and a surface of the third light-emitting subunit away from the base plate 100, i.e., the first light-emitting subunit 311 is thinner than the third light-emitting subunit. The three light-emitting subunits emit light of different colors, and the first light-emitting subunit 311 is the thinnest in the thickness direction z. Depending on a different pixel arrangement for the display panel 10, the thinnest light-emitting subunit may be a light-emitting subunit that emits one of red light, green light, or blue light.

In some embodiments, the first light-emitting subunit 311 and the second light-emitting unit 320 may be manufactured in a same manufacturing process, that is, the first light-emitting subunit 311 and the second light-emitting unit 320 may be evaporated and formed simultaneously.

In the display panel 10 according to the embodiments of the present application, the light-emitting subunits of different colors are sequentially evaporated during manufacturing, and the second light-emitting unit 320 can be evaporated simultaneously in a same process as the thinnest light-emitting subunit, additional processing steps are not required, and thus the transmittance of the display panel 10 can be further increased.

Referring to FIG. 2 and FIG. 14, FIG. 14 shows an enlarged schematic structural diagram of the position B in FIG. 1 in yet another example. FIG. 14 shows an enlarged schematic structural diagram after hiding of the conductive layer.

In some optional embodiments, the plurality of first openings 220 are distributed and spaced apart from each other, and each of the first openings 220 is provided with a corresponding one of the second sub-electrodes 420.

In some embodiments, the display panel 10 includes the plurality of first light-emitting units 310, which are distributed in rows along a first direction (the direction x in the figure) and columns along a second direction (the direction y in the figure), each of the first openings 220 is located between two adjacent rows of the plurality of first light-emitting units 310, and overlaps with two or more first light-emitting units 310 along the second direction x, as shown in FIG. 2. The first direction x is a row direction and the second direction y is a column direction. In some embodiments, the plurality of isolation openings 210 are distributed in rows along the first direction x and columns along the second direction y, each of the first openings 220 is located between two adjacent rows of the isolation openings 210 and overlaps with two or more isolation openings 210 along the second direction x.

In some embodiments, as shown in FIG. 14, the isolation opening 210 is surrounded by multiple ones of the first openings 220.

In the display panel 10 according to the embodiments of the present application, each of the first openings 220 is disposed corresponding to a plurality of first light-emitting units 310, which increases a distribution area of the first opening 220 and further improves the light transmittance of the display panel 10.

Continuing to reference to FIG. 5, in some optional embodiments, the display panel 10 may further include an encapsulation layer 800 disposed at a side of the first electrodes 400 away from the base plate 100, at least a part of the encapsulation layer 800 contacts with the isolation structure 200.

In some embodiments, the encapsulation layer 800 may include a first encapsulation layer 810, and the first encapsulation layer 810 includes a plurality of first encapsulation units 811 disposed at a side of the first electrodes 400 away from the base plate 100 and spaced apart from each other, at least a part of the first encapsulation unit 811 covers a side wall of the isolation structure 200 facing to the isolation opening 210 and extends to a side of the isolation structure 200 away from the base plate 100, and at least a part of the first encapsulation unit 811 further covers a side wall of the isolation structure 200 facing to the first opening 220 and extends to the side of the isolation structure 200 away from the base plate 100. The first encapsulation unit 811 is configured to encapsulate the isolation opening 210 and the first opening 220 to reduce an oxidative attack of external moisture on devices in the isolation opening 210 and the first opening 220, so as to improve lifetime of the display panel 10.

In some embodiments, the first encapsulation layer 810 may include an inorganic material. That is, the first encapsulation layer 810 may be an inorganic encapsulation layer, and may be manufactured using a chemical vapor deposition method, which can improve density of the first encapsulation layer 810, so as to improve encapsulation effects of the encapsulation layer 800.

In some embodiments, the encapsulation layer 800 may further includes a second encapsulation layer 820 disposed at a side of the first encapsulation layer 810 away from the base plate 100, the second encapsulation layer 820 may include an organic material. That is, the second encapsulation layer 820 may be an organic encapsulation layer, and may be manufactured using ink-jet printing method such that the encapsulation layer 800 has a suitable thickness.

In some embodiments, the encapsulation layer 800 may further includes a third encapsulation layer disposed at a side of the second encapsulation layer 820 away from the base plate 100, and the third encapsulation layer 830 may include an inorganic material. That is, the third encapsulation layer 830 may be an inorganic encapsulation layer. By providing an additional inorganic encapsulation layer outside the organic encapsulation layer, encapsulation effects of the encapsulation layer 800 can be further improved.

In some embodiments, the third encapsulation layer 830 may include a same material as the first encapsulation layer 810, such that the first encapsulation layer 810 and the third encapsulation layer 830 can be manufactured using a same equipment, so that the manufacturing process of the display panel can be simplified.

In some embodiments, the second sub-conductive layer 520 is located at a side of the encapsulation layer 800 away from the base plate 100.

In some optional embodiments, each of the first encapsulation units 811 covers only a corresponding opening, that is, one of the first encapsulation units 811 covers only one isolation opening 210 or first opening 220, and the first encapsulation units 811 for adjacent openings are not connected.

Referring to FIG. 8, FIG. 8 shows a cross-sectional view of FIG. 2 at the line A-A in yet another example.

In some optional embodiments, the first encapsulation layer 810 may further include a plurality of second encapsulation units 812 disposed at a side of the first electrodes 400 away from the base plate 100 and spaced apart from each other, at least a part of the second encapsulation units 812 covers a side wall of the isolation structure 200 facing to the isolation opening 210 and extends to a side of the isolation structure 200 away from the base plate 100, and at least a part of the second encapsulation unit 812 further covers a side wall of the isolation structure 200 facing to the first opening 220 and extends to a side of the isolation structure 200 away from the base plate 100. At least a part of the second encapsulation units 812 further covers a side wall of the isolation structure 200 facing to the isolation opening 210 and extends to a side wall of the isolation structure 210 facing to the first opening 220 adjacent to the isolation structure 210, that is, at least a part of the second encapsulation units 812 extends from the isolation opening 210 accommodating the first light-emitting subunit 311 to the first opening 220 accommodating the second light-emitting unit 320 adjacent to the isolation opening 210.

In some embodiments, an orthographic projection of the isolation opening 210 accommodating the first light-emitting subunit 311 on the base plate 100 and an orthographic projection of the first opening 220 adjacent to the isolation opening 210 on the base plate 100 are located within an orthographic projection of the second encapsulation unit 812 on the base plate 100. That is, the second encapsulation unit 812 encapsulates the isolation opening 210 accommodating the first light-emitting subunit 311 and the first opening 220 adjacent to the isolation opening 210 together.

In some embodiments, the light-emitting unit 300 may further includes third light-emitting unit 330s disposed between the isolation structure 200 and the second encapsulation units 812, and the third light-emitting unit 330 may include a same material of the first light-emitting unit 310, i.e., the third light-emitting unit 330 may be manufactured by a same manufacturing process as the first light-emitting unit 310. An orthographic projection of the third light-emitting unit 330 on the base plate 100 is located between an orthographic projection of the first light-emitting unit 310 adjacent to the third light-emitting unit 330 on the base plate 100 and an orthographic projection of the second light-emitting unit 320 adjacent to the third light emitting unit 330 on the base plate 100.

In some embodiments, the plurality of light-emitting units 300 may further include a plurality of third light-emitting units 330 disposed between the isolation structure 200 and the second encapsulation units 812, and the third light-emitting unit 330 may include a same material as that of the first sub-light emitting unit 311 and the second light-emitting unit 320 adjacent to the third light-emitting unit 330, that is, the third light-emitting unit 330 may be manufactured by a same manufacturing process as the first sub-light emitting unit 311 and the second light-emitting unit 320 adjacent to the third light-emitting unit 330. The third light-emitting unit 330 is spaced apart from the first sub light-emitting unit 311 and the second light-emitting unit 320. The orthographic projection of the third light emitting unit 330 on the base plate 100 is located between an orthographic projection of the first sub-light emitting unit 311 adjacent to the third light-emitting unit 330 on the base plate 100 and an orthographic projection of the second light-emitting unit 320 adjacent to the third light-emitting unit 330 on the base plate 100.

In some embodiments, each of the first electrodes 400 may further includes a third sub-electrode 430 disposed between the third light-emitting unit 330 and the second encapsulation unit 812. The third sub-electrode 430 is spaced apart from the first sub-electrode 410 and the second sub-electrode 420. An orthographic projection of the third sub-electrode 430 on the base plate 100 is located between the first sub-electrode 410 and the second sub-electrode 420 adjacent to the third sub-electrode 430, where the first sub-electrode 410 is a first sub-electrode 410 electrically connected with the first light-emitting subunit 311.

In the display panel 10 according to the embodiments of the present application, since the first light emitting subunit 311 includes a same material as the second light-emitting unit 320 and evaporated in a same process as the second light-emitting unit 320, an evaporation material will also adhere to an upper surface of the isolation structure 200 between the isolation opening 210 and the first opening 220 during evaporation, i.e., adhere to the third light-emitting unit 330 and the third sub-electrode 430. The isolation opening 210 accommodating the first sub-light emitting unit 311 and the adjacent first opening 220 can be integrally encapsulated by the second encapsulation unit 812 to reduce oxidative attack of external moisture on the devices in the isolation opening 210 and the first opening 220. Since the second encapsulation unit 812 integrally encapsulates the isolation opening 210 and the adjacent first opening 220, the third light-emitting unit 330 and the third sub-electrode 430 evaporated on the upper surface of the isolation structure 200 between the isolation opening 210 and the first opening 220 will also be encapsulated by the second encapsulation unit 812 and will not be removed in a subsequent process.

Referring to FIGS. 1 to 15, FIG. 15 shows an enlarged schematic structural diagram of the position B in FIG. 1 in yet another example.

As shown in FIGS. 1 to 15, the embodiments of the second aspect of the present application further provides a display panel 10, including a base plate 100, an isolation structure 200 and a plurality of sub-pixels 11, wherein the isolation structure 200 is disposed on a side of the base plate 100, and a plurality of isolation openings 210 and first openings 220 are surrounded by the isolation structure. The sub-pixels 11 includes a plurality of light-emitting sub-pixels 111 and a plurality of dummy sub-pixels 112. At least a part of the light-emitting sub-pixels 111 are disposed in the isolation openings 210, and at least a part of the dummy sub-pixels 112 are disposed in the first openings 220.

In some embodiments, when the display panel 10 is in use, the light-emitting sub-pixels 111 emit light, while the dummy sub-pixels 112 does not emit light.

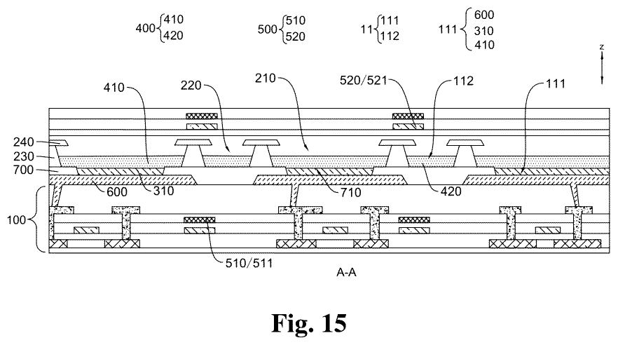

In some optional embodiments, the light-emitting sub-pixel 111 may include a second electrode 600, a first light-emitting unit 310 and a first sub-electrode 410 which are stacked along a direction away from the base plate 100, as shown in FIG. 15.

In some embodiments, the second sub-electrodes 420 and at least a part of the first sub-electrodes 410 may be formed in a same process.

In some embodiments, the dummy sub-pixel 112 may further include a second light-emitting unit 320 disposed at a side of the second sub-electrode 420 facing to the base plate, as shown in FIG. 3. The second light-emitting unit 320 may be formed in a same process as the first light-emitting unit 310.

In the display panel 10 according to the embodiments of the present application, the first opening 220 may be a light-transmitting opening, so as to improve the transmittance the display panel 10, which in turn facilitates implementation of an under-screen camera and improves imaging effects of the under-screen camera. In addition, the first opening 220 may be used for accommodating a fingerprint wiring, so as to reduce an overall thickness of the display panel 10. By providing the second sub-electrode 420 in the first opening 220, the second sub-electrode 420 can function as a shielding layer, so as to reduce a parasitic capacitance generated in the display panel 10 and improve the operational performance of the display panel 10. By enabling simultaneous evaporation of the second light-emitting unit 320 and the first light-emitting unit 310 and of the second sub-electrode 420 and the first sub-electrode 410, the second light-emitting unit 320 and the second sub-electrode 420 can be manufactured without requiring additional steps, so as to simplify a flow and reduce costs of manufacturing the display panel 10.

Embodiments of a third aspect of the present application also provide a display device including the display panel 10 according to any one of the embodiments of the first aspect or the display panel 10 according to any one of the embodiments of the second aspect. Since the display device according to the embodiments of the third aspect of the present application includes the display panel 10 according to any one of the embodiments of the first aspect, the display device according to the embodiments of the third aspect of the present application has the same beneficial effects as the display panel 10 according to any one of the embodiments of the first aspect, which is not repeated herein.

In some optional embodiments, the display device may further include an optical sensor (not shown) disposed at a side of the display panel 10, an orthographic projection of the optical sensor on the base plate 100 at least partially overlaps with the orthographic projection of the first opening 220 on the base plate 100.

In the display device according to the embodiments of the present application, since the orthographic projection of the optical sensor on the base plate 100 overlaps with the orthographic projection of the first opening 220 on the base plate 100, the first opening 220 facilitates implementation of an under-screen camera and under-screen fingerprint wirings or the like and improvement of imaging effects of the under-screen camera and a recognition accuracy on the under-screen fingerprint wrings.

The display device according to the embodiments of the present application includes, but is not limited to a mobile phone, a personal digital assistant (PDA), a tablet computer, e-book, a television, an access control, a smart fixed phone, a console and other devices with a display function.

Although the present application has been described with reference to the preferred embodiments, various modifications can be made thereto and components thereof can be replaced with their equivalents without departing from the scope of the present application. In particular, various technical features described in various embodiments can be combined in any manner as long as there is no structural conflict. The present application is not limited to the specific embodiments described herein, and includes all technical solutions that fall within the scope of the claims.

What is claimed is:

1. A display panel, comprising:
a base plate;
a plurality of second electrodes disposed on the base plate and spaced apart from each other;
an isolation structure, the isolation structure and the second electrodes are disposed at a same side of the base plate;
a plurality of isolation openings and first openings surrounded by the isolation structure, the second electrode being exposed from the isolation opening, and an orthographic projection of the second electrode on the base plate is offset from an orthographic projection of the first opening on the base plate;
a plurality of light-emitting units comprising a plurality of first light-emitting units and a plurality of second light-emitting units, the first light-emitting units are disposed in the isolation openings and located at a side of the second electrodes away from the base plate, and the second light-emitting units are disposed in the first openings; and
a plurality of first electrodes comprising a plurality of first sub-electrodes and a plurality of second sub-electrodes, the first sub-electrodes being disposed in the isolation openings, and located at a side of the first light-emitting units away from the base plate, at least a part of the first sub-electrode contacting with an inner wall of the isolation structure facing to the isolation opening, the second sub-electrodes being disposed in the first openings and located at a side of the second light-emitting units away from the base plate, and at least a part of the second sub-electrode contacting with an inner wall of the isolation structure facing to the first opening.

2. The display panel according to claim 1, further comprising:
a conductive layer comprising a first sub-conductive layer disposed in the base plate and a second sub-conductive layer disposed at a side of the isolation structure away from the base plate, the first sub-conductive layer comprises a first signal line, and the second sub-conductive layer comprises a second signal line;
the orthographic projection of the first opening on the base plate is at least partially located outside of an orthographic projection of the first signal line on the base plate; or
the orthographic projection of the first opening on the base plate is at least partially located outside of an orthographic projection of the second signal line on the base plate; or
the orthographic projection of the first opening on the base plate is located outside of the orthographic projection of the first signal line on the base plate, and the orthographic projection of the first opening on the base plate is located outside of the orthographic projection of the second signal line on the base plate.

3. The display panel according to claim 2, wherein
an orthographic projection of the isolation opening on the base plate is at least partially located outside of the orthographic projection of the second signal line on the base plate, or
the orthographic projection of the second signal line on the base plate overlaps with or is located within an orthographic projection of the isolation structure on the base plate; and
the orthographic projection of the second signal line on the base plate is located outside of an orthographic projection of the first light-emitting unit on the base plate, and the orthographic projection of the second signal line on the base plate is located outside of an orthographic projection of the second light-emitting unit on the base plate.

4. The display panel according to claim 2, wherein
a width of the orthographic projection of the second signal line on the base plate is less than a distance between the isolation opening and the first opening adjacent to just the isolation opening on the isolation structure; or
the width of the orthographic projection of the second signal line on the base plate is less than a distance between the adjacent isolation openings on the isolation structure.

5. The display panel according to claim 2, wherein the orthographic projection of the second signal line on the base plate is a grid mesh with second openings surrounded by the second signal line, and an orthographic projection of at least one of openings surrounded by the isolation structure on the base plate overlaps with or is located within an orthographic projection of the second opening on the base plate;
the openings surrounded by the isolation structure correspond to the second openings in a one-to-one correspondence;
orthographic projections of at least two of the openings surrounded by the isolation structure on the base plate are located within an orthographic projection of a same one of the second openings on the base plate; and
a plurality of openings surrounded by the isolation structure and located in a same one of the second openings are the isolation openings, or are the first openings, or include both the isolation openings and the first openings.

6. The display panel according to claim 1, wherein the isolation structure comprises an isolation wall and a barrier portion, the barrier portion is disposed at a side of the isolation wall away from the base plate, an orthographic projection of the isolation wall on the base plate is located within an orthographic projection of the barrier portion on the base plate, and at least a part of the second sub-electrode covers a side wall of the isolation wall facing to the first opening.

7. The display panel according to claim 6, wherein the isolation wall includes an electrically conductive material, and first sub-electrodes within at least two adjacent isolation openings are electrically connected with the second sub-electrode within the first opening through the isolation wall.

8. The display panel according to claim 6, wherein the first openings are surrounded by the isolation wall, and an orthographic projection of the second sub-electrode on the base plate overlaps with the orthographic projection of the first opening on the base plate; and
the first opening is a light-transmitting opening.

9. The display panel according to claim 1, wherein the first light-emitting units comprises a first light-emitting subunit and a second light-emitting subunit which emit light of different colors, and a distance between a surface of the first light-emitting subunit facing to the base plate and a surface of the first light-emitting subunit away from the base plate is less than a distance between a surface of the second light-emitting subunit facing to the base plate and a surface of the second light-emitting subunit away from the base plate.

10. The display panel according to claim 1, wherein
the distance between the surface of the first light-emitting subunit facing to the base plate and the surface of the first light-emitting subunit away from the base plate is equal to the distance between a surface of the second light-emitting unit facing to the base plate and a surface of the second light-emitting unit away from the base plate.

11. The display panel according to claim 9, wherein the first light-emitting subunit includes a same material as the second light-emitting unit, and
the first light-emitting subunit and the second light-emitting unit are manufactured by a same manufacturing process.

12. The display panel according to claim 9, wherein the first light-emitting units further comprises a third light-emitting subunit, the first light-emitting subunit, the second light-emitting subunit and the third light-emitting subunit are configured to emit one of red light, green light or blue light, respectively, and the distance between the surface of the first light-emitting subunit facing to the base plate and the surface of the first light-emitting subunit away from the base plate is less than a distance between a surface of the third light-emitting subunit facing to the base plate and a surface of the third light-emitting subunit away from the base plate.

13. The display panel according to claim 1, wherein the light-emitting unit further comprises a plurality of third light-emitting units disposed at a side of the isolation structure away from the base plate, an orthographic projection of the third light-emitting unit on the base plate is located between an orthographic projection of the first light-emitting unit adjacent to the third light-emitting unit on the base plate and an orthographic projection of the second light-emitting unit adjacent to the third light-emitting unit on the base plate; and the first electrode further comprises a third sub-electrode, disposed at a side of the third light-emitting unit away from the base plate, and an orthographic projection of the third sub-electrode on the base plate is located between an orthographic projection of the first sub-electrode adjacent to the third sub-electrode on the base plate and an orthographic projection of the second sub-electrode adjacent to the third sub-electrode on the base plate.

14. The display panel according to claim 1, further comprising:
an insulation layer disposed on the base plate and including a plurality of pixel openings, an orthographic projection of the pixel opening on the base plate is located within the orthographic projection of the isolation opening on the base plate, and the pixel opening is configured to accommodate the first light-emitting unit;
the insulating layer is a pixel definition layer, and the isolation structure is disposed at a side of the pixel definition layer away from the base plate, or the insulating layer includes a plurality of abdicating openings, at least a part of the base plate is exposed from the abdicating openings, and the isolation structure is disposed on the part of the base plate exposed from the abdicating openings; and
the pixel definition layer is provided with recesses or openings for accommodating the second light-emitting units at a side of the pixel definition layer away from the base plate.

15. The display panel according to claim 1, wherein the first openings are distributed and paced apart from each other, and each of the first openings is provided with a corresponding one of the second sub-electrodes;
the isolation openings are distributed in rows along a first direction and columns along a second direction, each of the first openings is located between two adjacent rows of the isolation openings and overlaps with two or more isolation openings along the second direction, wherein each of the first direction and the second direction intersects with a thickness direction of the display panel; and
the isolation opening is surrounded by multiple ones of the first openings.

16. The display panel according to claim 1, further comprising:
an encapsulation layer disposed at a side of the first electrodes away from the base plate, at least a part of the encapsulation layer contacts with the isolation structure;
the encapsulation layer comprises a first encapsulation layer, and the first encapsulation layer comprises a plurality of first encapsulation units disposed at a side of the first electrodes away from the base plate and spaced apart from each other, at least a part of the first encapsulation unit covers a side wall of the isolation structure facing to the isolation opening and extends to a side of the isolation structure away from the base plate, and at least a part of the first encapsulation unit further covers a side wall of the isolation structure facing to the first opening and extends to the side of the isolation structure away from the base plate;
the first encapsulation layer further comprises second encapsulation units disposed at a side of the first electrodes away from the base plate and spaced apart from each other, and at least a part of the second encapsulation unit covers a side wall of the isolation structure facing to the isolation opening and extends to a side wall of the isolation structure facing to the first opening adjacent to the isolation opening.

17. The display panel according to claim 1, wherein
the encapsulation layer further comprises a second encapsulation layer disposed at a side of the first encapsulation layer away from the base plate, and a third encapsulation layer disposed at a side of the second encapsulation layer away from the base plate,
the second encapsulation layer comprises an organic material, and the third encapsulation layer comprises an inorganic material or a same material as the first encapsulation layer.

18. A display panel, comprising:
a base plate;
an isolation structure disposed at a side of the base plate,
a plurality of isolation openings and first openings surrounded by the isolation structure; and
a plurality of sub-pixels comprising a plurality of light-emitting sub-pixels and a plurality of dummy sub-pixels, at least a part of the light-emitting sub-pixels are disposed in the isolation openings, and at least a part of the dummy sub-pixels are disposed in the first openings.

19. The display panel according to claim 18, wherein the light-emitting sub-pixel comprises a second electrode, a first light-emitting unit and a first sub-electrode which are stacked along a direction away from the base plate, and the dummy sub-pixel comprises a second sub-electrode;
the second sub-electrodes and at least a part of the first sub-electrodes are formed in a same process; and
the dummy sub-pixel comprises a second light-emitting unit disposed at a side of the second sub-electrode facing to the base plate.

20. A display device, comprising the display panel according to claim 1, and further comprising an optical sensor disposed at a side of the display panel, an orthographic projection of the optical sensor on the base plate at least partially overlaps with the orthographic projection of the first opening on the base plate.
